(19) United States
(12) Patent Application Publication
(10) Pub. No.: US 2026/0280221 A1
(43) Pub. Date: Sep. 17, 2026

(54) HIGH-PRECISION TUNABLE LASER CONTROL SYSTEM BASED ON PULSE WIDTH REGULATION

(71) Applicant: Hefei Institutes of Physical Science, Cas, Hefei (CN)

(72) Inventors: Qing Zang, Hefei (CN); Jian Zhou, Hefei (CN)

(21) Appl. No.: 19/295,696

(22) Filed: Aug. 11, 2025

(30) Foreign Application Priority Data
Mar. 14, 2025 (CN) 202510305035.4

(51) Int. Cl. H01S 3/13; H01S 3/08

(52) U.S. Cl. CPC H01S 3/1305; H01S 3/08009

(57) ABSTRACT

The present invention provides a high-precision tunable laser control system based on pulse width regulation, relating to the field of electrical digital data processing. The system includes a pulse width regulation module, a laser drive module, an optical tuning module, a feedback control module, and a man-machine interaction module. The pulse width regulation module is configured to dynamically regulate a pulse width, the laser drive module is configured to drive and generate laser, the optical tuning module is configured to regulate the wavelength of the laser, the feedback control module is configured to monitor the output laser and perform feedback regulation, and the man-machine interaction module is configured to set laser parameters. The system enables analysis and computation based on real-time errors, and feeds back analysis results to a control component for regulation, thereby achieving high-precision laser output.

### CROSS REFERENCE TO RELΔTED APPLICΔTIONS

The present application claims the benefit of Chinese Patent Application No. 202510305035.4 filed on Mar. 14, 2025, the contents of which are incorporated herein by reference in their entirety.

### TECHNICAL FIELD

The present invention belongs to the field of electrical digital data processing, and specifically relates to a high-precision tunable laser control system based on pulse width regulation.

### BACKGROUND

With the rapid development of optoelectronic technology and laser technology, tunable lasers are increasingly widely used in the fields of optical communication, spectral analysis, precision measurement, medical diagnosis, etc. Tunable lasers can output laser of different wavelengths as required, and have become an important component of modern optoelectronic systems due to their flexible wavelength regulation, high precision, and strong stability. However, in practical applications, conventional laser control systems still face challenges in terms of wavelength tuning precision, dynamic response speed, stability, etc.

### SUMMARY

To solve the above technical problems, the present invention provides a high-precision tunable laser control system based on pulse width regulation, which enables analysis and computation based on real-time errors, and feeds back analysis results to a control component for regulation, thereby achieving high-precision laser output.

To achieve the above objective, the present invention adopts the following technical solution:

A high-precision tunable laser control system based on pulse width regulation includes a pulse width regulation module, a laser drive module, an optical tuning module, a feedback control module, and a man-machine interaction module, where
the man-machine interaction module is configured to set target wavelength, power and pulse width parameters; the pulse width regulation module generates corresponding drive signals according to the settings of the man-machine interaction module; the laser drive module excites a laser to output optical signals based on the drive signals; the optical tuning module dynamically regulates a laser wavelength to a target value; the feedback control module monitors output in real time and performs correction processing;
the pulse width regulation module includes a pulse width generation unit, where the pulse width generation unit generates the drive signals with tunable pulse width based on preset parameters, and the drive signals are combined with signal modulation and timing control to achieve fine regulation of laser output;
the optical tuning module includes a grating tuning unit and a loop compensation unit, where the grating tuning unit implements precise spectral range scanning through a microelectromechanical system, and the loop compensation unit is configured to eliminate dynamic errors induced by mechanical regulation; and
the feedback control module includes a closed-loop control unit, where the closed-loop control unit regulates parameters based on detection signals and feeds the regulated parameters back to the laser drive module and the optical tuning module to achieve closed-loop control.

Further, the pulse width regulation module includes a signal modulation unit and a timing control unit, where the signal modulation unit is configured to regulate the frequency and amplitude of the drive signals, and the timing control unit is configured to control trigger time of pulse signals; and
the laser drive module includes a power regulation unit and a current drive unit, where the power regulation unit dynamically regulates drive current based on pulse width signals, and the current drive unit transmits regulated current signals to a laser to generate highly stable laser output.

Further, the optical tuning module includes a wavelength selection unit, where the wavelength selection unit cooperates with a multi-mode interference filter to precisely extract optical signals of the target wavelength.

Further, the feedback control module includes an optical power detection unit and a closed-loop control unit, where the optical power detection unit monitors the power and wavelength of laser output in real time through a photodiode, and the closed-loop control unit regulates parameters based on detection signals and feeds the regulated parameters back to the laser drive module and the optical tuning module.

Further, the man-machine interaction module includes an interface display unit and a parameter setting unit, where the interface display unit is configured to display actual status information of laser, and the parameter setting unit is configured to input control parameters.

Further, the grating tuning unit includes a grating element, a rotatable regulation mechanism, and a position sensor, where the grating element is configured to implement diffraction and separate the wavelength of incident light, the rotatable regulation mechanism is configured to regulate a grating angle and dynamically change the direction of diffracted light, and the position sensor is configured to detect the grating angle in real time and provide feedback.

Further, the closed-loop control unit includes an error detector, a control computing processor, and an execution drive processor, where the error detector is configured to detect an error between an actual value and a target value and generate an error signal, the control computing processor is configured to compute a regulation strategy, and the execution drive processor is configured to transmit regulation signals to an execution component.

The beneficial effects of the present invention are as follows: The present invention utilizes high-precision pulse width regulation technology, that is, combines pulse width tunable drive signals with signal modulation and timing control, to achieve fine regulation of laser output, thereby improving the stability of laser power and wavelength. The present invention further adopts intelligent feedback closed-loop control, that is, optical power detection and closed-loop control to monitor laser output in real time, and dynamically regulates drive current and optical tuning parameters to achieve precise power and wavelength control, thereby effectively reducing the impact of environmental interference on system performance. The present invention can achieve high precision and rapid response in optical tuning, that is, achieve nano-scale wavelength resolution and rapid wavelength switching by combining grating tuning with multi-mode interference filtering and using microelectromechanical system-based dynamic spectral scanning, thereby improving system adaptability. The present invention detects the status of laser and computes a deviation after the laser is output, and regulates control parameters based on the deviation to ensure that the status of laser is closer to a target status, where the control parameters are not directly regulated based on the deviation, but regulated after the deviation is subjected to computational processing, making the precision of regulation higher and meeting high laser requirements.

### BRIEF DESCRIPTION OF THE DRAWINGS

FIG. 1 is a schematic diagram of an overall structural framework of a high-precision tunable laser control system based on pulse width regulation in the present invention;

FIG. 2 is a schematic composition diagram of a pulse width regulation module;

FIG. 3 is a schematic composition diagram of an optical tuning module;

FIG. 4 is a schematic composition diagram of an optical power detection unit;

FIG. 5 is a schematic composition diagram of a closed-loop control unit; and

FIG. 6 is an actual test error effect diagram of the present invention.

### DETAILED DESCRIPTION

The following embodiments will further elaborate relevant technical content of the present invention, but the disclosed content is not intended to limit the scope of protection of the present invention.

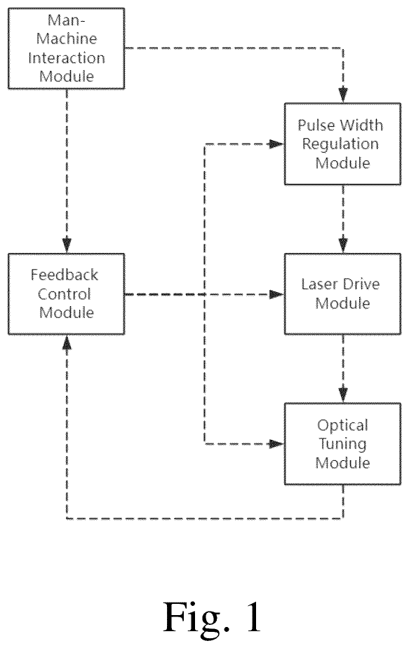

As shown in FIG. 1, an embodiment provides a high-precision tunable laser control system based on pulse width regulation, including a pulse width regulation module, a laser drive module, an optical tuning module, a feedback control module, and a man-machine interaction module.

The pulse width regulation module is configured to dynamically regulate a pulse width, the laser drive module is configured to drive the generation of laser, the optical tuning module is configured to regulate the wavelength of the laser, the feedback control module is configured to monitor the output laser and implement feedback regulations, and the man-machine interaction module is configured to set laser parameters.

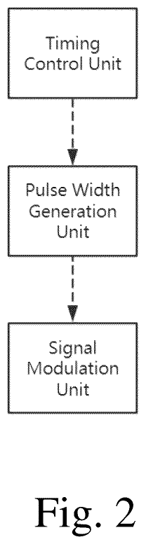

As shown in FIG. 2, the pulse width regulation module includes a pulse width generation unit, a signal modulation unit, and a timing control unit, where the pulse width generation unit generates drive signals with tunable pulse widths based on preset parameters, the signal modulation unit is configured to regulate the frequency and amplitude of the drive signals, and the timing control unit is configured to control trigger time of pulse signals.

The pulse width generation unit includes a clock generator, a pulse width controller, and a logic trigger, where the clock generator is configured to provide a stable reference time base, the pulse width controller generates pulse signals of a specific width based on pulse width parameters, and the logic trigger is configured to precisely start or stop a pulse generation process.

The signal modulation unit includes a modulation controller, a modulation signal generator, and a mixer, where the modulation controller is configured to receive modulation parameters and manage modulation modes, the modulation signal generator is configured to generate fundamental wave signals for modulation, and the mixer is configured to mix the pulse signals with the fundamental wave signals. The timing control unit includes a clock divider, a delay regulator, and a signal distributor, where the clock divider is configured to divide a high-frequency clock into required low-frequency clocks, the delay regulator is configured to add a delay to clock signals for event synchronization, and the signal distributor is configured to distribute timing signals to each module that needs to be controlled.

The laser drive module includes a power regulation unit and a current drive unit, where the power regulation unit dynamically regulates drive current based on the pulse width signals, and the current drive unit transmits regulated current signals to a laser to generate highly stable laser output.

The power regulation unit includes a power controller and a protection circuit, where the power controller is configured for overall computation and regulation of power, and the protection circuit is configured to monitor overvoltage, overcurrent, etc. and provide trigger protection;

The current drive unit includes a constant current source, a drive amplification processor, and a current monitoring processor, where the constant current source is configured to provide base current, the drive amplification processor is configured to amplify current signals, and the current monitoring processor is configured to detect output current in real time.

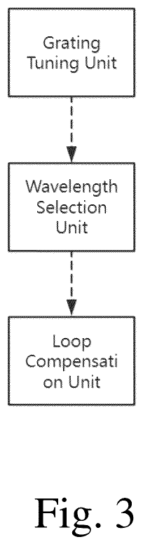

As shown in FIG. 3, the optical tuning module includes a grating tuning unit, a wavelength selection unit, and a loop compensation unit, where the grating tuning unit implements precise spectral range scanning through a microelectromechanical system, the wavelength selection unit cooperates with a multi-mode interference filter to precisely extract optical signals of a target wavelength, and the loop compensation unit is configured to eliminate dynamic errors induced by mechanical regulation.

The grating tuning unit includes a grating element, a rotatable regulation mechanism, and a position sensor, where the grating element is configured to implement diffraction and separate the wavelength of incident light, the rotatable regulation mechanism is configured to regulate a grating angle to dynamically change the direction of diffracted light, and the position sensor is configured to detect the grating angle in real time and provide feedback;

The wavelength selection unit includes a tunable filter, a wavelength selection mirror group, and a signal detector, where the tunable filter is configured to precisely allow the target wavelength to pass and filter out other wavelengths, the wavelength selection mirror group is configured to reflect and guide the optical signals of the target wavelength, and the signal detector is configured to verify the output wavelength and intensity;

The loop compensation unit includes an environmental detector, a compensation driver, and a filter suppression processor, where the environmental detector is configured to monitor the impact of environmental interference on system output, the compensation driver is configured to regulate physical system components, and the filter suppression processor is configured to suppress high-frequency noise introduced during compensation.

The feedback control module includes an optical power detection unit and a closed-loop control unit, where the optical power detection unit monitors the power and wavelength of the laser output in real time through a photodiode, and the closed-loop control unit regulates parameters based on detection signals and feeds the regulated parameters back to the laser drive module and the optical tuning module.

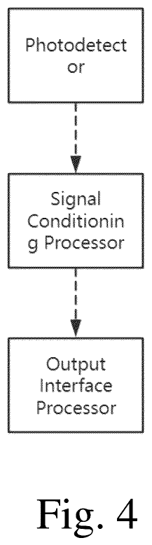

As shown in FIG. 4, the optical power detection unit includes a photodetector, a signal conditioning processor, and an output interface processor, where the photodetector is configured to convert input optical signals into electrical signals proportional to the power and wavelength, the signal conditioning processor is configured to filter, shape, and normalize the converted electrical signals, and the output interface processor is configured to output detected power signals to other modules.

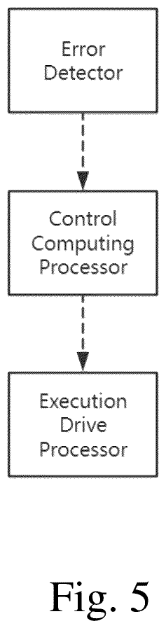

As shown in FIG. 5, the closed-loop control unit includes an error detector, a control computing processor, and an execution drive processor, where the error detector is configured to detect an error between an actual value and a target value and generate an error signal, the control computing processor is configured to compute a regulation strategy, and the execution drive processor is configured to transmit regulation signals to an execution component.

The interface display unit includes a real-time information display processor and a deviation information display processor, where the real-time information display processor is configured to display real-time status information of laser and physical components, and the deviation information display processor is configured to display deviation information of the laser;

The parameter setting unit includes a parameter input processor and a parameter response processor, where the parameter input processor is configured to input parameter information, and the parameter response processor is configured to collect the input parameter information and transmit the parameter information to remaining modules.

The control computing processor computes a regulation angle Δθ of a grating according to the following equation:

$$Δ θ = arcsin ( \frac{m \cdot Δλ}{d} + sin θ ) - θ$$

where m represents a diffraction order, Δλ represents a wavelength deviation, d represents a grating period, and θ represents a current grating diffraction angle.

The control computing processor computes regulated drive current I_{new} according to the following equation:

$${I}_{n e w} = \frac{{I}_{c} \cdot Δ P}{{I}_{c} \cdot η - Δ P} + {I}_{c} ;$$

where ΔP represents a power deviation, η represents laser efficiency, and I_{c} represents current drive current.

The control computing processor computes regulated pulse width trigger time t_{new} according to the following equation:

$${t}_{n e w} = \frac{{t}_{c}}{1 - \frac{Δ T}{T}} ;$$

where t_{c} represents current pulse width trigger time, ΔT represents a pulse width deviation, and T represents a set pulse width.

The man-machine interaction module includes an interface display unit and a parameter setting unit, where the interface display unit is configured to display actual status information of laser, and the parameter setting unit is configured to input control parameters.

A working process of the high-precision tunable laser control system based on pulse width regulation according to an embodiment of the present invention includes the following steps:
S1. Set target wavelength, power and pulse width parameters in the man-machine interaction module;
S2. Utilize the pulse width regulation module to generate corresponding drive signals;
S3. Utilize the laser drive module to excite the laser to output optical signals based on the drive signals;
S4. Utilize the optical tuning module to dynamically regulate the laser wavelength to a target value;
S5. Utilize the feedback control module to monitor the output in real time and perform correction processing;

Specifically, in S5, the control computing processor of the feedback control module computes a regulation angle Δθ of the grating according to the following equation:

$$Δ θ = arcsin ( \frac{m \cdot Δλ}{d} + sin θ ) - θ ;$$

where m represents a diffraction order, Δλ represents a wavelength deviation, d represents a grating period, and θ represents a current grating diffraction angle;

The control computing processor computes regulated drive current I_{new} according to the following equation:

$${I}_{n e w} = \frac{{I}_{c} \cdot Δ P}{{I}_{c} \cdot η - Δ P} + {I}_{c} ;$$

where ΔP represents a power deviation, η represents laser efficiency, and I_{c} represents current drive current;

The control computing processor computes regulated pulse width trigger time t_{new} according to the following equation:

$${t}_{n e w} = \frac{{t}_{c}}{1 - \frac{Δ T}{T}} ,$$

where t_{c} represents current pulse width trigger time, ΔT represents a pulse width deviation, and T represents a set pulse width.

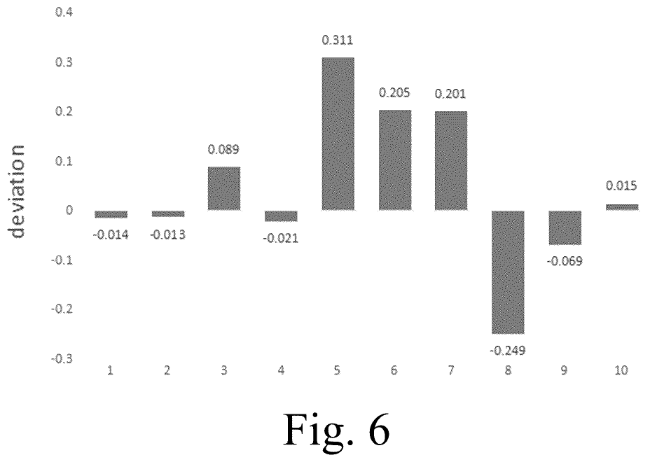

By using the present invention, 10 beams of laser of different power (as indicated by numbers 1 to 10 in FIG. 6) were generated, actual values were tested, and their comparison effects shown in FIG. 6 were obtained.

What is claimed is:

1. A high-precision tunable laser control system based on pulse width regulation, wherein through optical power detection and closed-loop control, laser output is monitored in real time, and drive current and optical tuning parameters are dynamically regulated, to achieve precise power and wavelength control; nano-scale wavelength resolution and rapid wavelength switching are achieved by combining grating tuning with multi-mode interference filtering and using microelectromechanical system-based dynamical spectral scanning, and wherein the high-precision tunable laser control system comprises:
a pulse width regulation module, a laser drive module, an optical tuning module, a feedback control module, and a man-machine interaction module, wherein
the man-machine interaction module is configured to set target wavelength, power and pulse width parameters; the pulse width regulation module generates corresponding drive signals according to the settings of the man-machine interaction module; the laser drive module excites a laser to output optical signals based on the drive signals; the optical tuning module dynamically regulates a laser wavelength to a target value; the feedback control module monitors output in real time and performs correction processing;
the pulse width regulation module comprises a pulse width generation unit, wherein the pulse width generation unit generates the drive signals with tunable pulse width based on preset parameters, and the drive signals are combined with signal modulation and timing control to achieve fine regulation of laser output;
the optical tuning module comprises a grating tuning unit and a loop compensation unit, wherein the grating tuning unit implements precise spectral range scanning through a microelectromechanical system, and the loop compensation unit is configured to eliminate dynamic errors induced by mechanical regulation;
the feedback control module comprises a closed-loop control unit, wherein the closed-loop control unit regulates parameters based on detection signals and feeds the regulated parameters back to the laser drive module and the optical tuning module to achieve closed-loop control;
the closed-loop control unit comprises a control computing processor, wherein the control computing processor computes a regulation angle Δθ of a grating according to the following equation:
$$Δ θ = arcsin ( \frac{m \cdot Δλ}{d} + sin θ ) - θ ;$$
wherein m represents a diffraction order, Δλ represents a wavelength deviation, d represents a grating period, and θ represents a current grating diffraction angle;
the control computing processor computes regulated drive current I_{new} according to the following equation:
$${I}_{n e w} = \frac{{I}_{c} \cdot Δ P}{{I}_{c} \cdot η - Δ P} + {I}_{c} ;$$
wherein ΔP represents a power deviation, η represents laser efficiency, and I_{c} represents current drive current;
the control computing processor computes regulated pulse width trigger time t_{new} according to the following equation:
$${t}_{n e w} = \frac{{t}_{c}}{1 - \frac{Δ T}{T}} ;$$
wherein t_{c} represents current pulse width trigger time, ΔT represents a pulse width deviation, and T represents a set pulse width.

2. The high-precision tunable laser control system based on pulse width regulation according to claim 1, wherein the pulse width regulation module further comprises a signal modulation unit and a timing control unit, wherein the signal modulation unit is configured to regulate the frequency and amplitude of the drive signals, and the timing control unit is configured to control trigger time of pulse signals; and
the laser drive module comprises a power regulation unit and a current drive unit, wherein the power regulation unit dynamically regulates drive current based on pulse width signals, and the current drive unit transmits regulated current signals to a laser to generate highly stable laser output.

3. The high-precision tunable laser control system based on pulse width regulation according to claim 1, wherein the optical tuning module further comprises a wavelength selection unit, wherein the wavelength selection unit cooperates with a multi-mode interference filter to precisely extract optical signals of the target wavelength.

4. The high-precision tunable laser control system based on pulse width regulation according to claim 1, wherein the feedback control module further comprises an optical power detection unit, wherein the optical power detection unit monitors the power and wavelength of laser output in real time through a photodiode.

5. The high-precision tunable laser control system based on pulse width regulation according to claim 1, wherein the man-machine interaction module comprises an interface display unit and a parameter setting unit, wherein the interface display unit is configured to display actual status information of laser, and the parameter setting unit is configured to input control parameters.

6. The high-precision tunable laser control system based on pulse width regulation according to claim 3, wherein the grating tuning unit comprises a grating element, a rotatable regulation mechanism, and a position sensor, wherein the grating element is configured to implement diffraction and separate the wavelength of incident light, the rotatable regulation mechanism is configured to regulate a grating angle and dynamically change the direction of diffracted light, and the position sensor is configured to detect the grating angle in real time and provide feedback.

7. The high-precision tunable laser control system based on pulse width regulation according to claim 4, wherein the closed-loop control unit comprises an error detector and an execution drive processor, wherein the error detector is configured to detect an error between an actual value and a target value and generate an error signal, and the execution drive processor is configured to transmit regulation signals to an execution component.
